(19) United States
(12) Patent Application Publication
(10) Pub. No.: US 2026/0359701 A1
(43) Pub. Date: Nov. 12, 2026

(54) SYSTEMS, METHODS AND DEVICES FOR INFLUENCING OPERATING STATES OF QUANTUM SYSTEMS

(71) Applicant: PHOTONIC INC., Coquitlam (CA)

(72) Inventor: Gary WOLFOWICZ, Vancouver (CA)

(21) Appl. No.: 19/136,180

(22) PCT Filed: Dec. 5, 2023
(86) PCT No.: PCT/CA2023/051612

§ 371 Date: Jun. 5, 2025

Related U.S. Application Data
(60) Provisional application No. 63/387,461, filed on Dec. 14, 2022.

(51) Int. Cl. G06N 10/60

(52) U.S. Cl. CPC G06N 10/60

(57) ABSTRACT

In a method for influencing an operating state of a quantum system, the quantum system comprises at least one defect, defect complex or impurity in a host material. A transition between different energy levels of the at least one defect, defect complex or impurity is determined. The transition has a transition energy that is a function of an external electric field and/or external mechanical stress. The transition energy has a critical point. A bias electric field and/or a bias mechanical stress is determined for bringing the transition energy of the at least one defect, defect complex or impurity to or close to the critical point. The external electric field comprises the bias electric field and an environmental noise electric field. The external mechanical stress comprises the bias mechanical stress and an environmental noise mechanical stress. The determined bias electric field and/or mechanical stress is applied to the quantum system.

### CROSS-REFERENCE TO RELATED APPLICATION

This application claims priority from U.S. application No. 63/387,461 filed 14 Dec. 2022 and entitled SYSTEMS, METHODS AND DEVICES FOR INFLUENCING OPERATING STATES OF QUANTUM SYSTEMS which is hereby incorporated herein by reference for all purposes. For purposes of the United States of America, this application claims the benefit under 35 U.S.C. § 119 of U.S. application No. 63/387,461 filed 14 Dec. 2022 and entitled SYSTEMS, METHODS AND DEVICES FOR INFLUENCING OPERATING STATES OF QUANTUM SYSTEMS which is hereby incorporated herein by reference for all purposes.

### FIELD

This disclosure generally relates to quantum systems and more particularly to systems, methods and devices for influencing an operating state of a quantum system.

### BACKGROUND

Classical computing involves the manipulation of data in the form of binary values. Quantum computing, in contrast, involves the preparation and manipulation of quantum states. For two-state quantum systems, qubits can be in a superposition of two basis states |0 [symbol] and |1 [symbol] . Quantum states have peculiar properties, such as interference and entanglement, which are not present in the classical realm. It is expected that quantum computers of sufficient size and complexity are more efficient than classical computers in performing certain applications, such as solving certain mathematical problems, including integer factorization, the discrete logarithm problem and the elliptic-curve discrete logarithm problem which underlying modern encryption methods.

### SUMMARY

Practical implementations of quantum computers can involve the entanglement of spins through photons. In particular, optically active spin centres in silicon photonic networks have been identified as promising elements of such potential quantum computers. Among those photon-spin centres are so-called T centres, comprising two carbon atoms, one hydrogen atom and an unpaired electron. T centres are described in Safonov et al., “Carbon-Hydrogen Deep Level Luminescence Centre in Silicon Responsible for the T-Line,” Materials Science Forum, vol. 196-201, pp. 909-914 (1995). T centres have particularly interesting properties, such as long-lived electron spins and nuclear spins and sharp, spin-dependent telecommunications-band optical transitions. Higginbottom et al., “Optical observation of single spins in silicon,” Nature 607, pp. 266-270 (2022) discuss the integration of individually addressable T centre photon-spin qubits in silicon photonic structures and characterize their spin-dependent telecommunications-band optical transitions.

The implementation of quantum computers faces practical problems because realistic solid-state quantum systems are never completely isolated from their environment. Uncontrolled or noisy interaction between quantum systems and their environment leads to an alteration of the quantum state of the quantum system. The environment noise may originate from classical sources, for example a magnetic field antenna or nearby laser light. Environment noise may also originate from interaction of the quantum system under consideration with other quantum systems in the proximity, i.e., within an interaction range. For example, noise from a quantum source can arise from placing several qubits in proximity to one another such that they mutually interfere with each other, i.e., there is crosstalk between the qubits.

Decoherence can originate from thermal vibrations (phonons) of the surrounding lattice. Strain can have an influence on such thermal phonons, as discussed in Sohn et al., “Controlling the coherence of a diamond spin qubit through its strain environment,” Nat. Commun. 9, 2012 (2018).

The detrimental effect of the environment on the quantum system can be alleviated by minimizing noise from the source. In applications, however, control over interfering sources is typically limited. Therefore, certain background noise remains and the effects of the background noise must be reduced by other means. Therefore, it is desirable to reduce the sensitivity of the quantum system to effects originating from a noise source.

The present disclosure has several aspects, including systems, methods, and devices for influencing an operating state of a quantum system. The quantum system may include one or more qubits.

A first aspect of the disclosure provides a method for influencing an operating state of a quantum system. The quantum system comprises at least one defect, defect complex or impurity in a host material. A transition between different energy levels of the at least one defect, defect complex or impurity is determined such that a transition energy of the transition has a critical point, where the gradient of the transition energy as a function of an external electric field and/or an external mechanical stress is zero or close to zero. The external electric field comprises the bias electric field and an environmental noise electric field. The external mechanical stress comprises the bias mechanical stress and an environmental noise mechanical stress. The bias electric field and/or a bias mechanical stress is determined for bringing the at least one defect, defect complex or impurity to or close to the critical point of the transition energy. The method also involves causing the determined bias electric field and/or the determined bias mechanical stress to be applied to the quantum system.

The method helps to reduce the environmental noise influences on a quantum system by operating the quantum system within a sub-space where the quantum state of the quantum system is insensitive to environmental fluctuations. The quantum system is brought to a critical point of the transition energy as a function of the external electric field and/or external mechanical stress. Electric fields and mechanical stresses can affect the bound-exciton transition energy and can be used to suppress noise from environmental electric fields and mechanical stress.

By reducing the effect of environmental noise on the quantum system, the transition energy of the quantum system can be stabilized. This means that the photon frequency associated with a transition is known to a good degree, which again implies that the quality of emitted photons is controlled. This is highly beneficial for operations involving entanglement, where one needs indistinguishable photons for generating entanglement between quantum systems.

Environmental fluctuations correspond to small fluctuations in the environmental noise electric field and/or small fluctuations in the environmental noise mechanical stress. Fluctuations in environmental noise that may be accommodated may be within 0.01%, 0.1%, 1%, 2% or 5% of the environmental noise. Because the quantum system is at or close to the critical point of the transition energy, the fluctuations of the transition energy associated with the environmental fluctuations are very small. The quantum system is therefore in a robust state which is largely insensitive to environmental fluctuations.

In this specification, an “operating state” of a quantum system describes a quantum state of the quantum system or components/sub-systems of the quantum system. The operating state may depend on the external magnetic field, external electric field, and/or the external mechanical stress. In particular, the quantum system may be characterized by one or more transition energies that depend on the external magnetic field, external electric field, and/or external mechanical stress.

In this specification, the critical point of a transition energy corresponds to the region where the quantum system is robust to environmental noise fluctuations. For example, at the critical point, the transition energy is insensitive, up to first order (i.e., the gradient vanishes), to environmental noise influences.

In this specification, “close to a critical point” can mean that the transition energy is within a predefined range around the transition energy at the critical point. For example, the predefined may be within 0.01%, 0.1%, 1%, 2% or 5% of the transition energy at the critical point.

In this specification, the “environmental noise mechanical stress” and the “environmental noise electric field” are effects which are uncontrolled, or which can only be controlled within narrow limits.

In this specification, the term “stress” may comprise or be replaced by “strain”.

Environmental noise influences may comprise fluctuations due to charge noise. The environmental noise influences may also comprise surface effects and strain from differential thermal contraction. In general, environmental noise influences may be categorized into electric field fluctuations (i.e., environmental noise electric fields) and mechanical constraints and vibrations (i.e., environmental noise mechanical stress).

According to an embodiment of the method according to the first aspect, only one of the bias electric field and the bias mechanical stress is applied to the quantum system. In other embodiments, a combination of the bias electric field and the bias mechanical stress is applied to the quantum system. For example, a bias mechanical stress can be applied globally, while a bias electric field is applied locally for final control or vice versa.

Global or local control can be determined based on the need to minimize cross-talk between qubits, power dissipation and switching speed of the controls.

According to an embodiment of the method according to the first aspect, the bias electric field is determined such that the vector sum of the bias electric field and the environmental noise electric field is equal to or close to the value of the external electric field at the critical point. In addition or alternatively, the bias mechanical stress is determined such that the sum of the bias mechanical stress and the environmental noise mechanical stress is equal to or close to the value of the external mechanical stress at the critical point. In general, the effect of the mechanical stress can be slightly different from the effect of the electric field due to symmetry consideration on the wavefunction of the at least one defect.

According to an embodiment of the method according to the first aspect, the transition between different energy levels comprises a transition between energy levels associated with different spins, orbital quantum numbers or any other quantum number.

According to an embodiment of the method according to the first aspect, the critical point of the transition energy is determined using a model that describes the quantum system. The bias electric field and/or the bias mechanical stress is determined such that the at least one defect, defect complex or impurity is at or close to the determined critical point of the transition energy. The model can be a physical model and can comprise interactions of degrees of freedom of the quantum system with external influences such as the external electric field and the external mechanical stress.

According to an embodiment of the method according to the first aspect, the model comprises a Hamiltonian function of the quantum system. Determining the critical point of the transition energy comprises determining a critical point of the Hamiltonian function. The Hamiltonian function can comprise interaction terms such as an effective coupling of the degrees of freedom of the Hamiltonian to the external electric field and/or mechanical stress. For example, the Hamiltonian function may comprise an effective term leading to a Stark effect which describes the influence of an external electric field on the energy levels.

According to an embodiment of the method according to the first aspect, the critical point of the transition energy is selected from a plurality of critical points associated with the transition energy. Herein, the plurality of critical points has been determined using the model. The bias electric field and/or the bias mechanical stress is determined for bringing the at least one defect, defect complex or impurity to or close to the selected critical point of the transition energy. For some quantum systems, there may exist a plurality of energy branches and one or more of these branches may have a respective critical point. Accordingly, the transition branch having a critical point that meets one or more predetermined conditions may be selected.

According to an embodiment of the method according to the first aspect, a critical point of the plurality of critical points is selected based on the first-order gradient of the transition energy at the critical point. For example, the selected critical point may have a first-order gradient that is smaller than a predetermined value or number. Furthermore, the selected critical point may have the smallest second-order gradient or higher-order gradient amongst the plurality of critical points. Herein, the gradient of the transition energy is computed as a function of the external electric field and/or the electric mechanical stress. The transition energy may have the following functional dependence:

$$\frac{{dE}_{t}}{dx} = a + b \cdot ( x - {x}_{0} ) + c \cdot {( x - {x}_{0} )}^{2} + d \cdot {( x - {x}_{0} )}^{3} + ⋯ ,$$

where x denotes the external electric field or the electric mechanical stress. At the critical point, x₀, dEₜ/dx is zero (or close to zero) and b is zero (or close to zero). That is, a critical point can be identified if the parameter b is smaller than a predefined value. Moreover, there may exist several critical points. In this case, a critical point can be selected having the smallest value of c and/or d, and so on.

According to an embodiment of the method according to the first aspect, a critical point of the plurality of critical points is selected which is reachable by causing the bias electric field to be applied and/or by causing the bias mechanical stress to be applied within a predetermined and practically controllable range. In this way, one can avoid selecting critical points which are not reachable in practice, for example because the electric field required to reach the critical point is larger than the electric field that can be provided (i.e., the electric field is outside of the bias range).

According to an embodiment of the method according to the first aspect, a critical point of the plurality of critical points is selected based on a predefined quantum operation to be performed on the quantum system. The predefined quantum operation may be an entanglement operation, which requires photons with a particular wavelength. The selection of the critical point can be based on a desired optimal compromise between the insensitivity to environmental effects, whether the bias to be applied is within the available bias range, a preselected transition energy range or a transition probability. Herein, an excitation may be achieved by applying laser light to the quantum system. The transition probability (or transition rate) describes how fast the excitation is. The transition probability may change as a function of external electrical fields and/or external mechanical stresses. According to an embodiment, only critical points that have a transition probability above a predefined threshold are selected.

According to an embodiment of the method according to the first aspect, a measurement result characteristic of the quantum system is obtained from a measurement on the quantum system. Obtaining the measurement result may involve performing the measurement or receiving the measurement. The model describing the quantum system is selected based on the measurement result. For example, the model may have free parameters which are determined based on the measurement result.

According to an embodiment of the method according to the first aspect, the measurement comprises a determination of the energy levels of the quantum system and of at least one quantum number of the energy levels. The quantum number of the energy levels may comprise spin quantum numbers or orbital quantum numbers.

According to an embodiment of the method according to the first aspect, the measurement comprises a determination of the nature and/or types of interactions that are characteristic of the quantum system. For example, the interactions may comprise at least one of a Zeeman interaction, a Stark interaction, or a hyperfine interaction. Herein, a Zeeman interaction can relate to the coupling of the total electronic angular momentum of an atom of the defect to an external magnetic field, which results in a splitting of different energy levels. The Stark effect relates to a splitting of the energy levels of the defect in the presence of electric fields. A hyperfine interaction can relate to electromagnetic interactions involving a nuclear spin of an atom of the defect which is affected by external electromagnetic fields, again resulting in a splitting of different energy levels.

Respective strengths of the interactions can be measured, and a respective interaction term is included in the Hamiltonian (e.g., a Zeeman interaction term or a hyperfine interaction term), where the coupling strength is determined according to the measured strength of the interaction.

According to an embodiment of the method according to the first aspect, the measurement comprises a measurement of piezoelectric properties of the host material (substrate) of the quantum system.

According to an embodiment of the method according to the first aspect, the measurement comprises a measurement of a coherence time of the quantum system.

According to an embodiment of the method according to the first aspect, the measurement comprises a determination of a symmetry of the at least one defect, defect complex or impurity. For example, the measurement may comprise an electron spin resonance measurement for determining the symmetry of the defect from observation of fine structure effects. Possible symmetries may comprise any one or combination of inversion symmetry, an axial symmetry, or a point group symmetry (e.g., an involutional symmetry, a Cₙ cyclic symmetry, a Dₙ dihedral symmetry, a Ta symmetry, or a Cₙᵥ symmetry).

According to an embodiment of the method according to the first aspect, the measurement comprises a measurement of a signal intensity of an optical signal emitted by the at least one defect, defect complex or impurity. The optical signal can be measured using a photodetector and an amplitude of the optical signal can be determined.

According to an embodiment of the method according to the first aspect, the measurement comprises a measurement of a spectrum of the at least one defect, defect complex or impurity. The spectrum may be obtained by a photoluminescence excitation (PLE) measurement.

According to an embodiment of the method according to the first aspect, the measurement comprises a measurement of a homogeneous linewidth of a spectrum of the at least one defect, defect complex or impurity. The homogeneous linewidth can be determined using the spectral hole burning method. According to this method, a sample with an inhomogeneous broadened absorption band is irradiated with a narrow-based laser. Resonant absorption of photons will create a hole in the original absorption band at the laser wavelength, for example due to the presence of a shelving state. The hole can be probed with a tunable laser and the homogeneous linewidth can be inferred from the spectral width of the hole.

According to an embodiment of the method according to the first aspect, the measurement comprises a measurement of an inhomogeneous linewidth of a spectrum of the at least one defect, defect complex or impurity. The inhomogeneous linewidth gives the likelihood of finding multiple qubits at the right frequency, and therefore of having high fidelity. The inhomogeneous linewidth can be determined from the measured spectrum. The inhomogeneous linewidth (inhomogeneous broadening) relates to the variations in ensemble of qubits (e.g., defects).

According to an embodiment of the method according to the first aspect, the measurement comprises a measurement of a transition energy of the transition. The transition energy can be determined from a photoluminescence (PL) measurement. The measurement may comprise the measurement of a zero-phonon line (ZPL) transition energy.

According to an embodiment of the method according to the first aspect, the measurement comprises a measurement of a size and/or orientation of the environmental noise electric field and/or the environmental noise mechanical stress. For example, the environmental noise electric field may be directly measured, e.g., using a capacitor or other charge sensor located near or at least partly within the host substrate.

According to an embodiment of the method according to the first aspect, the measurement comprises a measurement of a size and/or orientation of the bias electric field and/or the bias mechanical stress.

According to an embodiment of the method according to the first aspect, a result of a measurement performed on the quantum system is obtained and the bias electric field and/or the bias mechanical stress are determined, based on a result of the measurement. Obtaining the measurement result may involve performing the measurement or receiving the measurement result. The measurement can comprise any of the above-described measurements or any combination of these measurements. In some embodiments, the bias electric field and/or the bias mechanical stress can be determined directly from the measurement results, without relying on a model that describes the quantum system.

According to an embodiment of the method according to the first aspect, the measurement comprises a photoluminescence (PL) measurement of the quantum system, a measurement of a homogeneous linewidth (e.g., from spectral hole burning as described above), or a measurement of an inhomogeneous linewidth of a spectrum of the at least one defect (e.g., from the PL measurement results).

According to an embodiment of the method according to the first aspect, the photoluminescence measurement comprises a measurement of a spectral density of the environmental noise. The spectral density of the environmental noise can be measured by monitoring fast changes in the signal or the center wavelength over time. As will be appreciated by those of skill in the art, other measurements may be performed in characterizing the environmental noise.

According to an embodiment of the method according to the first aspect, the bias electric field and/or the bias mechanical stress is determined using a look up table (LUT), based on the result of the measurement. For each measurement (which may include one or more data points), at least one respective value for the bias electric field and/or the bias mechanical stress is deduced from the LUT. The LUT may have been determined based on previous measurements on the quantum system or on similar quantum systems.

According to an embodiment of the method according to the first aspect, the at least one defect comprises a luminescent defect. The transition comprises an optical transition. In particular, the at least one defect may comprise a spin defect. A particular example of a luminescent defect is a T centre.

According to an embodiment of the method according to the first aspect, the transition comprises a zero-phonon line, ZPL, transition. In a ZPL transition, an optical photon is emitted but no phonon is generated.

According to an embodiment of the method according to the first aspect, a result of measurement performed on the quantum system is obtained. Obtaining the measurement result may involve performing the measurement or receiving the measurement. At least one figure of merit, FOM, of the quantum system is determined based on the measurement result. The FOM describes a robustness of the quantum system against environmental noise. As will be appreciated, a quantum system is said to be robust against environmental noise if the quantum system is insensitive to environmental noise. The applied bias electric field and/or the applied bias mechanical stress is applied to bring the at least one FOM within a predetermined range. For example, a control method can be used to vary the applied bias electric field and/or mechanical stress. The control method ends if the FOM is above a predetermined threshold value, i.e., if the quantum system is at or close to a critical point of the transition energy and is sufficiently robust against environmental noise. In other embodiments, the FOM may be actively tracked/monitored, such that when the FOM falls below the predetermined threshold value, a feedback signal is generated that triggers the control method.

The FOMs describe certain characteristics or parameters that quantify the robustness of a qubit to the noisy environment. The FOMs are sensitive to the interaction between the at least one defect and the immediate environment.

The at least one FOM can comprise inhomogeneous broadening (an inhomogeneous linewidth), e.g., determined from a PLE spectrum of the quantum system. A low value implies more repeatability of the properties of the quantum system, which is important for scalability.

The at least one FOM can comprise homogeneous broadening (a homogeneous linewidth) which relates to single qubit fluctuations. A low value implies that a single qubit frequency (i.e., transition energy) remains stable over time.

The at least one FOM can comprise a (bare) coherence time T*₂ (pure dephasing time), i.e., a coherence time if no additional refocusing is performed on the quantum system. The bare coherence time may be equivalent to the homogeneous broadening. A long bare coherence time implies highly coherent control, i.e., high fidelity can be achieved.

The at least one FOM can comprise a refocused coherence time T₂ (effective dephasing time), i.e., a coherence time if additional refocusing is performed on the quantum system. A long refocused coherent time implies long term quantum memory.

According to an embodiment of the method according to the first aspect, one of the applied bias mechanical stress and the applied bias electric field is homogeneous over the quantum system, and wherein the other of the applied bias mechanical stress and the applied bias electric field varies locally over the quantum system. In this embodiment, one of the bias electric field and bias mechanical stress is applied in an inhomogeneous manner. Inhomogeneous biasing can be used to obtain different behavior across different nearby quantum systems.

According to an embodiment of the method according to the first aspect, both the applied bias mechanical stress and the applied bias electric field may be locally varied over the quantum system. Different behavior of quantum systems can be achieved by varying both the bias mechanical stress and the bias electric field.

According to an embodiment of the method according to the first aspect, the bias mechanical stress can be adjusted. In particular, a strength and/or direction of the bias mechanical stress may be adjusted based on measurements performed on the quantum system.

According to an embodiment of the method according to the first aspect, the bias mechanical stress is applied by a piezoelectric actuator. By changing a voltage applied to the piezoelectric actuator, the strength of the mechanical stress can be adjusted.

According to an embodiment of the method according to the first aspect, the bias mechanical stress is generated by applying a clamping force. The clamping force can be adjusted in some embodiments to select a specific bias mechanical stress.

According to an embodiment of the method according to the first aspect, the quantum system comprises a plurality of layers, wherein the bias mechanical stress is applied by imposing a lattice mismatch between the plurality of layers. The lattice mismatch imposes strain the layers.

According to an embodiment of the method according to the first aspect, the bias mechanical stress is applied by adjusting a temperature of the quantum system. The change in temperature causes an expansion or contraction of the host material, which influences mechanical stress on the quantum system.

According to an embodiment of the method according to the first aspect, the host material having the at least one defect, defect complex or impurity comprises at least one deflectable structure, wherein applying the bias mechanical stress comprises deflecting the at least one deflectable structure. The host substrate may be in or on a membrane or cantilever, such that by deflecting the membrane or cantilever, the mechanical stress changes around the quantum system changes.

According to an embodiment of the method according to the first aspect, the bias electric field can be adjusted. In particular, a strength and/or direction of the bias electric field may be adjusted based on result of the measurements performed on the quantum system.

According to an embodiment of the method according to the first aspect, only a strength of the bias electric field is determined and adjusted, while the direction of the electric field is fixed. In another embodiment, both the strength and the direction of the electric field can be adjusted.

According to an embodiment of the method according to the first aspect, the bias electric field is applied using at least one capacitor. By changing a voltage applied to the capacitor, the electric field generated by the capacitor changes. In this way, the bias electric field can be adjusted. The capacitor may be located outside the host substrate or on the host substrate and may generate a bias electric field which is constant across the quantum system.

According to an embodiment of the method according to the first aspect, the capacitor is patterned, and the applied bias electric field may be locally varied. The capacitor may also be located locally on the host substrate or within the host substrate to generate a local electric field which affects only certain quantum systems of a plurality of quantum systems. Further, there can be a plurality of capacitors and each capacitor can be controlled independently.

According to an embodiment of the method according to the first aspect, the method may involve causing a quantum operation to be performed with the quantum system. Causing the quantum operation to be performed may involve performing the quantum operation or controlling another device to perform the quantum operation. The operation can comprise any practical application in quantum sensing, quantum computing or quantum information processing.

According to an embodiment of the method according to the first aspect, the applied bias electric field and/or bias mechanical stress is adjusted while performing the quantum operation or between successive quantum operations. The quantum system can therefore be calibrated online, i.e., during operation.

According to an embodiment of the method according to the first aspect, information about the environmental noise is determined based on the applied bias electric field and/or based on the applied bias mechanical stress. For example, a noise amplitude can be inferred. According to an embodiment, it is determined if the environmental noise electric field or the environmental noise mechanical stress is the main noise source.

According to an embodiment of the method according to the first aspect, the quantum system has a non-vanishing electric dipole moment, which makes the transition energy sensitive to electric fields.

According to an embodiment of the method according to the first aspect, the host material is a semiconductor substrate or a dielectric material.

According to an embodiment of the method according to the first aspect, the method runs at predefined calibration times. At each calibration time, the bias electric field and/or bias mechanical stress is determined and adjusted.

According to an embodiment of the method according to the first aspect, the bias electric field and/or the bias mechanical stress is applied dynamically. For example, the bias electric field and/or the bias mechanical stress can be time-dependent and can be adjusted such that the quantum system is only at the critical point only for a fraction of time. Afterwards, the bias electric field and/or the bias mechanical stress may be changed to move the quantum system away from the critical point.

According to an embodiment of the method according to the first aspect, causing the determined bias electric field and/or the determined bias mechanical stress to be applied to the quantum system involves outputting a control signal to cause the determined bias electric field and/or the determined bias mechanical stress to be applied to the quantum system.

According to an embodiment of the method according to the first aspect, causing the determined bias electric field and/or the determined bias mechanical stress to be applied to the quantum system comprises applying the determined bias electric field and/or the determined bias mechanical stress to the quantum system.

A second aspect of the disclosure provides a method for influencing an operating state of a quantum system. The quantum system comprises at least one defect, defect complex or impurity in a host material. The at least one defect, defect complex or impurity comprises a transition between different energy levels. A bias electric field and/or a bias mechanical stress is applied to the quantum system in step (a). A measurement is performed on the quantum system in step (b). At least one figure of merit, FOM, of the quantum system is determined, based on a result of the measurement in step (c). The FOM relates to a robustness of the quantum system against environmental noise. If the at least one FOM is outside a predetermined range, the bias electric field and/or the bias mechanical stress are adjusted and steps (a) to (c) are repeated with the adjusted bias electric field and/or the adjusted bias mechanical stress.

According to the second aspect, the bias electric field and/or the bias mechanical stress are controlled to optimize the at least one FOM, i.e., to increase the robustness of the quantum system against environmental noise.

According to an embodiment of the method according to the second aspect, the measurement comprises a photoluminescence measurement of the quantum system. The FOM can be a quantity that is influenced by environmental noise. The photoluminescence measurement may comprise a measurement of a homogeneous linewidth of a spectrum of the at least one defect, defect complex or impurity.

According to an embodiment of the method according to the second aspect, the photoluminescence measurement comprises a measurement of an inhomogeneous linewidth of a spectrum of the at least one defect, defect complex or impurity. The photoluminescence measurement may also comprise a measurement of a spectral density of the environmental noise.

According to an embodiment of the method according to the second aspect, a quantum operation is performed using the quantum system if the at least one FOM is within the predetermined range. The operation can comprise any practical application in quantum sensing, quantum computing or quantum information processing.

A third aspect of the disclosure provides a computer-implemented method for controlling an actuator. A result is received from a measurement performed on a quantum system. The quantum system comprises at least one defect, defect complex or impurity in a host material. The at least one defect, defect complex or impurity comprises a transition between different energy levels. A model is determined, describing the quantum system, based on the result of the measurement. At least one critical point of a transition energy of the transition is determined as a function of an external electric field and/or an external mechanical stress, using the determined model. A bias electric field and/or a bias mechanical stress is determined to bring the at least one defect, defect complex or impurity to or close to one critical point of the determined at least one critical point, using the determined model. At least one control signal is output to an actuator to control the actuator to apply the determined bias electric field and/or the determined bias mechanical stress to the quantum system.

According to an embodiment of the method according to the third aspect, the computing steps of the method up to the determination of the bias electric field and/or the bias mechanical stress to be applied to the quantum system are performed at a remote location, e.g., a global server.

A fourth aspect of the disclosure provides a device for influencing an operating state of a quantum system, wherein the quantum system comprises at least one defect, defect complex or impurity in a host material. A computing device determines a transition between different energy levels of the at least one defect, defect complex or impurity such that a transition energy of the transition as a function of an external electric field and/or an external mechanical stress has a critical point. The external electric field comprises the bias electric field and an environmental noise electric field. The external mechanical stress comprises the bias mechanical stress and an environmental noise mechanical stress. The computing device determines the bias electric field and/or a bias mechanical stress for bringing the at least one defect, defect complex or impurity to or close to the critical point of the transition energy. An actuator applies the determined bias electric field and/or the determined bias mechanical stress to the quantum system.

A fifth aspect of the disclosure provides a system, comprising a host substrate and a quantum system comprising at least one defect, defect complex or impurity in the host substrate. The system further comprises a device for influencing an operating state of the quantum system according to the fourth aspect.

A sixth aspect of the disclosure provides a device for influencing an operating state of a quantum system, wherein the quantum system comprises at least one defect, defect complex or impurity in a host material, wherein the at least one defect, defect complex or impurity comprises a transition between different energy levels. An actuator applies a bias electric field and/or a bias mechanical stress to the quantum system. A measurement device performs a measurement on the quantum system. A computing device determines at least one figure of merit, FOM, of the quantum system, based on a result of the measurement. The FOM relates to a robustness of the quantum system against environmental noise. If the at least one FOM is outside a predetermined range, the computing device controls the actuator to adjust the bias electric field and/or the bias mechanical stress.

A seventh aspect of the disclosure provides a system, comprising a host substrate, and a quantum system comprising at least one defect, defect complex or impurity in the host substrate. The system further comprises a device for influencing an operating state of the quantum system according to the sixth aspect.

An eighth aspect of the disclosure provides a device for controlling an actuator, the device comprises an interface configured to receive a result from a measurement performed on a quantum system, wherein the quantum system comprises at least one defect, defect complex or impurity in a host material. The at least one defect, defect complex or impurity comprises a transition between different energy levels. A computing device determines a model describing the quantum system, based on the result of the measurement. Using the model, the computing device determines at least one critical point of a transition energy of the transition. The transition energy is a function of an external electric field and/or an external mechanical stress. The computing device further determines a bias electric field and/or a bias mechanical stress to bring the at least one defect, defect complex or impurity to or close to one critical point of the determined at least one critical point, using the determined model. The computing device controls the interface to output at least one control signal to an actuator to control the actuator to apply the determined bias electric field and/or the determined bias mechanical stress to the quantum system.

A ninth aspect of the disclosure provides a system comprising a host substrate, a quantum system comprising at least one defect, defect complex or impurity in the host substrate, and an actuator configured to apply a bias electric field and/or a bias mechanical stress to the quantum system. The quantum system further comprises a device for controlling an actuator according to the eighth aspect.

A tenth aspect of the disclosure provides a computer program product comprising executable program code configured to, when executed by a computing device, perform the method according to any of the embodiments of the first, second or third aspect of the disclosure.

A eleventh aspect of the disclosure provides a non-transitory, computer-readable storage medium comprising executable program code configured to, when executed by a computing device, perform the method according to any of the embodiments of the first, second or third aspect of the disclosure.

The disclosure relates to all combinations of the above features, even if these are recited in different aspects or different claims.

### BRIEF DESCRIPTION OF THE DRAWINGS

In the following, further aspects and exemplary embodiments will be described with reference to the accompanying drawings. However, the present disclosure is not limited to the described exemplary embodiments described and may be modified in various different ways. Consequently, the drawings and description are intended to be illustrative in nature and not limiting. Identical reference numbers denote identical elements in the specification.

FIG. 1 schematically shows a block diagram illustrating a system according to an embodiment of the disclosure.

FIG. 2 shows an actuator system for applying a bias mechanical stress to a quantum system according to an embodiment.

FIG. 3 shows an actuator system for applying a bias mechanical stress to a quantum system according to a further embodiment.

FIG. 4 shows an actuator system for applying a bias mechanical stress to a quantum system according to a further embodiment.

FIG. 5 shows an actuator system for applying a bias electric field to a quantum system according to an embodiment.

FIG. 6 shows an actuator system for applying a bias electric field to a quantum system according to a further embodiment.

FIG. 7 schematically shows the dependence of a transition energy of a transition between different energy levels of a defect on an external mechanical stress and/or on an external electric field.

FIG. 8 shows an exemplary PLE spectrum obtained from an ensemble of T centres.

FIG. 9 shows an exemplary spectral hole burning measurement result corresponding to a first energy transition in the PLE spectrum of FIG. 8.

FIG. 10 shows an exemplary spectral hole burning measurement result corresponding to a second energy transition in the PLE spectrum of FIG. 8.

FIG. 11 shows a flow diagram illustrating a method for influencing an operating state of a quantum system according to an embodiment.

FIG. 12 shows a flow diagram illustrating a method for influencing an operating state of a quantum system according to another embodiment.

FIG. 13 shows a flow diagram illustrating a computer-implemented method for controlling an actuator according to an embodiment.

### DETAILED DESCRIPTION

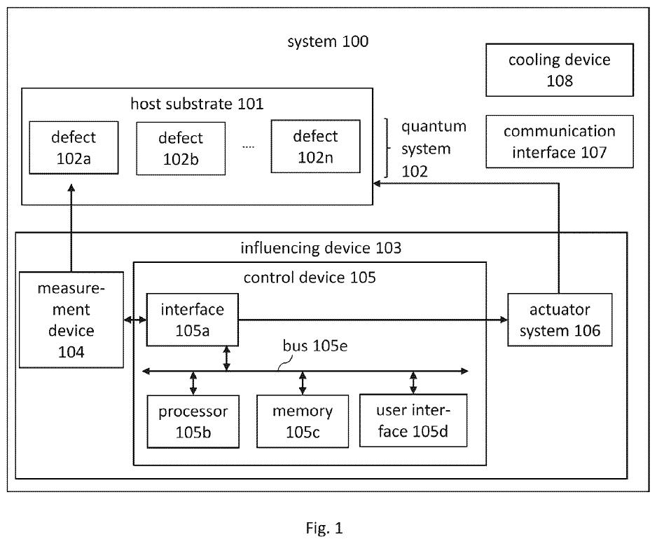

FIG. 1 schematically shows a block diagram illustrating a system 100 according to an embodiment of the disclosure. The system 100 may be used for any practical application in quantum sensing, quantum computing or quantum communication.

Quantum computing comprises any processing of information based on quantum effects such as superpositions of states of quantum systems 102, (de-)coherence or entanglement of quantum systems 102. The system 100 may have qubits that can be entangled with each other or with qubits of other systems 100.

Quantum communication comprises the transmission of classical information or of quantum states between different devices, e.g., between the system 100 and another system based on quantum effects as described above.

Quantum sensing comprises measurements which utilize quantum effects such as entanglement, interference of quantum state squeezing.

The system 100 comprises a host substrate 101 (or host material), which can be a semiconductor substrate or any dielectric material.

In some embodiments, the host substrate 101 (host material) may comprise Yttrium orthosilicate (YSO), Yttrium orthovanadate (YVO), hexagonal boron nitride (hBN) or diamond.

In some embodiments, the host substrate 101 may comprise silicon, e.g., at least one of silicon carbide (SiC), single crystal silicon (e.g., Czochralski (CZ) silicon, or float zone (FZ) silicon), multicrystalline silicon, polycrystalline silicon (e.g., obtained by chemical-vapour deposition) or microcrystalline (e.g., obtained by plasma deposition). The host substrate may comprise enriched or purified silicon where non-zero-nuclear spin isotopes have been largely removed. For example, the host substrate 101 may comprise purified silicon having been enriched to various levels of silicon-28, such as 99%, 99.9%, or 99.99%. Defects in purified silicon generally have narrower spectroscopic linewidths.

In some embodiments, the host substrate 101 comprises at least 50 percent silicon by weight, at least 80 percent silicon by weight, or at least 90 percent silicon by weight.

The host substrate 101 may have a single layer or a plurality of layers. For example, a layer of purified silicon may be deposited or grown on top of a layer of natural silicon. The host substrate 101 may also comprise other materials, such as silicon carbide or silicon germanium.

The system 100 further comprises a quantum system 102, comprising at least one defect 102a to 102n disposed in the host substrate 101. Rather than or in addition to the defect 102a to 102n, the quantum system 102 may further comprise at least one defect complex or impurity in the host substrate 101. In the following, the system 100 is described in the context of defects in the host material 101 but it is to be understood by the skilled person that the host material 101 may also (or instead) comprise defect complexes or impurities.

The defect 102a to 102n may be located in the bulk of the host substrate 101 or in a layer of the host substrate 101 (e.g., a top layer of the host substrate 101). In other embodiments, the defect 102a to 102n is located close to a face, side or edge of the host substrate 101, e.g., within a distance smaller than 10 nm, 50 nm, 100 nm or 500 nm from the face, side or edge of the host substrate 101.

The defect 102a to 102n can be coupled to an optical structure of the system 100, for example at least one of a resonator, waveguide, lens, coupler, cavity or any other refractive and/or reflecting element. A photon emitted from the defect 102a to 102n can be coupled into the optical structure.

The defect 102a to 102n has two or more associated energy levels. Each energy level can be characterized by quantum numbers, such as spin or orbital momentum. The energy levels may also depend on the orientation of the defect 102a to 102n in the host material. The quantum system 102 may have a non-vanishing electric dipole moment, such that the transition energy is sensitive to electric fields.

The defect 102a to 102n may comprise at least one atom or atomic vacancies (e.g., silicon atom vacancies in a silicon host material). Multiple atoms can be located in specific orientations relative to one another and to the atoms of the host substrate 101. A given defect 102a to 102n may also have several different orientations relative to the host substrate 101.

The defect 102a to 102n may comprise a point defect, defect complexes and/or impurities. In the case of a point defect, the defect 102a to 102n may comprise a vacancy defect, an interstitial defect (i.e., an atom occupies a non-lattice site), a substitutional defect (i.e., an atom in the lattice of the host substrate 101 is replaced by a different type of atom), a Schottky defect or a Frenkel defect (an atom of the lattice is displaced, leaves a vacancy and becomes interstitial).

The defect 102a to 102n can be a damage centre, e.g., a radiation damage centre, such as a radiation damage centre in a silicon host substrate 101. The defect 102a to 102n may have been created by applying radiation to the host substrate 101, e.g., by applying electron radiation to the host substrate 101. Thereafter, an annealing step at a predefined temperature may be performed to repair damage.

The defect 102a to 102n may comprise a luminescent defect which has at least two energy states which differ by a transition energy. If a first of the energy states decays into a second of the energy state, an optical photon with an energy corresponding to the transition energy is emitted. The optical photon has a wavelength in the ultraviolet, visible or infrared band of the electromagnetic spectrum. In a zero-phonon line transition (ZPL), only an optical photon is emitted but no phonon (i.e., collective excitation in the host substrate 101) is generated. The energy of the photon is called ZPL transition energy. For example, the defect 102a to 102n may have a ground state and at least one excited state. An excitation energy corresponds to each transition between an excited state and the ground state.

The defect 102a to 102n can be characterized by its physical properties, such as the ZPL transition energy. The characteristic properties of the defect 102a to 102n can depend on external parameters, for example, external electric field and/or external mechanical stress. As will be appreciated by those of skill in the art, mechanical stress may comprise or be replaced with mechanical strain.

In some embodiments, the defect 102a to 102n can comprise a nitrogen-vacancy center in a diamond substrate 101.

In some embodiments, the defect 102a to 102n can comprise a luminescent defect from at least one of Al1, C, F, G, Ga1, I, M, P, T, W, X centres in a silicon host substrate 101 or their equivalents obtained by isovalent or isoelectronic replacements or substitutions for one or more atoms in the defects 102a to 102n.

In some embodiments, the defect 102a to 102n comprises a T centre which is believed to comprise two bound carbon atoms which replace a single silicon atom in the host substrate 101, a hydrogen atom which is bound to one of the carbon atoms, and an unpaired electron.

T centres are promising spin-photon interface, having a narrow O-band optical transition (having a ZPL optical transition energy near 1326 nm) and long-lived electron and nuclear spin lifetimes. The O-band is a band used for fiber-optic communication where optical fibers have low loss. T centres may be oriented in any one of twelve orientational subsets. The electron spin qubits are coupled to the nuclear spin qubits through a hyperfine interaction and are further coupled to a photon qubit through an exciton optical transitions that emit photons.

The T centres may be generated in a silicon-on-isolator (SOI) host substrate 101 by ion implantation of carbon and hydrogen and thermal annealing. For example, the host substrate 101 can be a 220 nm device layer of a commercial SOI wafer. The device layer may comprise CZ natural silicon and may be located on a buried SiO₂ layer. High concentrations of T centres can be achieved by ion implantation and annealing. Moreover, the system 100 may operate as a fully-integrated quantum network, where spin-dependent emission of photons from the T centres, processing and detection can all occur within the SOI device layer.

The system 100 further comprises an influencing device 103 for influencing an operating state of the quantum system 102. The influencing device 103 comprises a measurement device 104, a control device 105, and an actuator system 106.

The measurement device 104 may comprise at least one laser device for optically exciting the quantum system 102. The laser light can have a predefined frequency (or wavelength). The frequency can also be tunable. The measurement device 104 may perform a measurement on the quantum system 102. For example, a resonant photoluminescence excitation may be obtained by sweeping the wavelength of a narrow-line tunable laser and by measuring the emitted photoluminescence, e.g., by a photon detector of the measurement device 104. Sweeping the wavelength of the laser may be achieved using a phase electro-optic modulator (EOM) of the measurement device 104.

The measurement device 104 may generate measurement results which depend on characteristics of the quantum system 102, e.g., the transition energy of the quantum system 102, a sensitivity of the quantum system 102 to environmental noise, and the like.

The measurement device 104 may perform a measurement which allows a determination of the energy levels of the quantum system 102. The measurement results may also allow a determination of at least one quantum number of the respective energy levels. Herein, the quantum number of the energy levels may comprise spin quantum numbers and/or orbital quantum numbers. The measurement performed by the measuring device may further comprise a determination of types of interactions and respective strengths of the interactions of the quantum system.

The measurement device 104 may also measure properties of the host substrate 101, e.g., piezoelectric properties of the host substrate 101. The measurement device 104 may further determine symmetries of the defect 102a to 102n, e.g., through an electron spin resonance measurement. The measurement device 104 may also determine a homogeneous linewidth of the spectrum of the defect 102a to 102n, e.g., using the spectral hole burning method. The measurement device 104 can also determine the inhomogeneous linewidth, e.g., through a PLE measurement.

The measurement device 104 may further measure the strength and/or direction of electromagnetic fields, in particular, of the environmental noise electric field and/or a bias electric field. The measurement device 104 may also measure a size and/or an orientation of mechanical stresses, in particular of the environmental noise mechanical stress and/or a bias mechanical stress.

The control device 105 comprises an interface 105a which is connected to the measurement device 104 and to the actuator system 106. The interface 105a comprises communication circuitry for bidirectional communication with the measurement device 104 and the actuator system 106 over a connection, e.g., an internet connection, a serial connection, a parallel connection, an ethernet connection, a wireless connection, a fiber optic connection or the like. The interface 105a may employ communication protocols such as FTP, HTTPS, SSH or TCP/IP to communicate. The interface 105a may also comprise a first interface for connecting the control device 105 with the measurement device 104 and a separate second interface for connecting the control device 105 with the actuator system 106.

The control device 105 comprises a processor 105b (i.e., a computing device). The processor 105b can be a logic processing unit and can comprise a central processing unit (CPU), a graphics processing unit (GPU), a microcontroller (μC), an integrated circuit (IC), an application-specific integrated circuit (ASIC), a digital signal processor (DSP), a field programmable gate array (FPGA), a program logic unit (PLU), a network processor (NP) or a combination thereof.

The control device 105 comprises a memory 105c which can comprise at least one of a magnetic hard disk, an optical disc (e.g., compact disc, digital video disc, Blu-ray disc), a solid state disc (SSD), a magneto-optical memory or a hard disc drive (HDD). For example, the memory 105c can comprise a volatile semiconductor or solid state memory, e.g., a random access memory (RAM), dynamic RAM (DRAM), or static RAM (SRAM). The memory 105c can comprise a non-volatile semiconductor or solid state memory, e.g., a read only memory (ROM), programmable ROM (PROM), erasable PROM (EPROM), or the like.

The memory 105c stores processor-executable instructions and/or processor-readable data associated with the operation of the control device 105. The processor-executable instructions and/or processor-readable data can comprise an operating system, peripheral drivers, server instructions, application instructions, calibration instructions, or communication channel instructions.

The processor 105b determines a transition between different energy levels of the at least one defect, defect complex or impurity 102a to 102n such that a transition energy of the transition as a function an external electric field and/or an external mechanical stress has a critical point.

Herein, the external electric field Eₑₓₜ is a vector which is the sum of a bias electric field E_{bias} and an environmental noise electric field Eₙₒᵢₛₑ:

Eₑₓₜ=E_{bias}+Eₙₒᵢₛₑ.

Herein, the environmental noise electric field Eₙₒᵢₛₑ is a field which is not readily controllable/avoidable, whereas the bias electric field E_{bias} can be adjusted by the actuator system 106.

Similarly, the external mechanical stress σₑₓₜ is a tensor which is the sum of a bias mechanical stress σ_{bias} and an environmental noise mechanical stress noise.

σₑₓₜ=σ_{bias}+σₙₒᵢₛₑ.

Herein, the environmental noise mechanical stress σₙₒᵢₛₑ is not readily controllable/avoidable whereas the bias mechanical stress σ_{bias} can be adjusted by the actuator system 106. Mechanical stress results when forces like tension or compression act on the host substrate 101. Stress can be expressed by the so-called Cauchy stress tensor which completely describes the stress state of a uniformly stressed body. In some embodiments, stress can also be described by a single number, e.g., in the event of uniaxial normal stress, simple shear stress or isotropic normal stress.

The processor 105b can use a physical model of the quantum system 102 to compute the transition energy as a function of the external electric field Eₑₓₜ and/or as a function of the external mechanical stress σₑₓₜ. The physical model can comprise a Hamiltonian function of the quantum system 102. The external electric field comprises the bias electric field and an environmental noise electric field as explained above. The external mechanical stress comprises the bias mechanical stress and an environmental noise mechanical stress as explained above.

The processor 105b determines a bias electric field and/or a bias mechanical stress for bringing the at least one defect, defect complex or impurity 102a to 102n to or close to the critical point of the transition energy.

Depending on the quantum system 102, there can occur a plurality of critical points of the transition energy. The processor 105b may then select a critical point according to at least one predefined criterion. In some embodiments, the processor 105b may consider higher-order gradients of the transition energy as a function of the external mechanical stress and/or external electric field (for example a second-order gradient or a third-order gradient). The processor 105b may for example select the critical point with the smallest second-order gradient amongst all the critical points.

In selecting the critical point from the plurality of critical points, the processor 105b may also take one or more intended applications of the system 100 into account. For example, the system 100 may be intended for use in performing one or more quantum operations. During the quantum operation, the defect 102a to 102n may be excited by applying laser light to the quantum system 102. The transition probability of such an excitation may depend on the external electrical field and/or the external mechanical stress. The processor 105b may only select critical points having corresponding critical external electrical fields and/or critical external mechanical stresses such that the transition probability is larger than a predefined value.

In selecting the critical point from the plurality of critical points, the processor 105b may also take into account whether a frequency of photons corresponding to the transition is predefined. For example, photons can be used for entanglement or other any other application that requires photons with a stable frequency. In this case, a critical point can be selected which corresponds to the desired frequency.

In general, the processor 105b may take several of the above criteria into account, i.e., an insensitivity to environmental effects (e.g., via higher-order gradients), the reachable range of bias electrical fields and/or bias mechanical stress, and applications (e.g., via the transition probability).

The processor 105b may further determine at least one figure of merit, FOM based on measurement results from the measurement device 104. The FOM may comprise at least one of inhomogeneous broadening, homogeneous broadening, a bare coherence time (pure dephasing time), or a refocused coherence time (effective dephasing time).

The effective dephasing time T₂ is inversely proportional to the intrinsic or homogeneous spectral linewidth which gives information on relaxation processes of the excited state. The effective dephasing time T₂ can be expressed in terms of the population decay time (or excited state lifetime) T₁ and the pure dephasing time T*₂ which is determined by thermally induced fluctuations of the transition frequency (due to phonon scattering and/or electron and nuclear spin fluctuations).

The control device 105 further comprises a user interface 105d, having at least one of a display, a keyboard, a touch screen, a mouse, buttons, a microphone, loudspeakers and the like. A user may provide or receive information regarding the operation of the system 100 via the user interface 105d. For example, the user may adjust the model describing the quantum system 102 via the user interface 105d or may receive measurement results obtained by the measurement device 104 via the user interface 105d.

All of the components of the control device 105 described above can be controlled and/or can communicate over at least one bus 105d. The processor 105b may be configured to control the other above-described components 105a, 105c, 105d of the control device 105.

The actuator system 106 may apply a bias electric field or a bias mechanical stress to the quantum system 102. The actuator system 106 may alternatively be referred to as the biasing system. The magnitude and/or direction of the bias electric field and/or the bias mechanical stress to be applied is predetermined by the processor 105b.

The actuator system 106 can comprise a plurality of actuators. For example, the actuator system 106 can comprise an electromagnet to apply a time-invariant electric field, a time-varying electric field or a pulsed electric field to the quantum system 102.

The actuator system 106 may further comprise a mechanical system for varying or applying a bias mechanical stress (bias strain) on the host substrate 101, in response to executing processor-executable instructions, e.g., in response to a control signal received from the processor 105b. By applying a bias mechanical stress, the actuator system 106 can effect changes in the energy eigenstates of the defect 102a to 102n and therefore in the transition energy.

The actuator system 106 may apply bias mechanical stress locally within or across the host substrate 101. Components of the mechanical system of the actuator system 106 may be disposed within the host substrate 101 (e.g., within the bulk of the host substrate 101) or may be arranged outside the host substrate 101 and may be mechanically coupled to the host substrate 101. The mechanical system may include at least one micro-electro-mechanical system (MEMS) component for applying the bias mechanical stress. The mechanical system may include at least one piezoelectric actuator.

The actuator system 106 may also apply bias mechanical stress by adjusting a temperature applied to the quantum system 102.

The actuator system 106 may apply both a bias electric field and a bias mechanical stress at the same time. In an embodiment, the actuator system 106 applies one of the bias electric field and the bias mechanical stress homogeneously and the other of the bias electric field and the bias mechanical stress inhomogeneously. Herein, the term “homogeneously” denotes that the electric field or mechanical stress, respectively, is applied essentially constant over the quantum system 102. In turn, the term “inhomogeneously” denotes that the electric field or mechanical stress, respectively, varies over the quantum system 102 (i.e., there is a gradient of the electric field or mechanical stress, respectively). For example, where the quantum system comprises more than one defect, each one having a different transition energy and different dependence on external electric field/mechanical stress, it may be advantageous to apply at least one of the bias electric field and bias mechanical stress inhomogeneously. Likewise, it may be advantageous to apply at least one of the bias electric field and bias mechanical stress homogenously, and then compensate for any undershoot/overshoot (relative to the critical point) by applying the other one of the bias electric field and bias mechanical stress inhomogenously.

According to further embodiments, the actuator system 106 applies both the bias electric field and the bias mechanical stress homogeneously or applies both the bias electric field and the bias mechanical stress inhomogeneously.

The actuator system 106 may be controlled to adjust the bias electric field and/or the bias mechanical stress during operation of the system 100.

The system 100 further comprises a communication interface 107 for connecting the system 100 with other systems comprising quantum and/or classical devices. For example, the communication interface 107 may be connected to a fiber optic link. A photon entangled with a defect 102a to 102n in the host substrate 101 may be coupled into the fiber optic link. The photon can then interact with a respective photon of another system to entangle the defect 102a to 102n with qubits (e.g., defects) of another system.

The communication interface 107 may also comprise circuitry to provide classical communication with external devices, e.g., for providing or receiving control signals to or from the external device. For example, an external server may control at least one of the components of the system 100 by providing a control signal over the communication interface 107. The communication interface 107 may comprise a parallel connection, a serial connection, an ethernet connection, an internet connection, a wireless connection, and the like.

The system 100 can further comprise a cooling device 108 to maintain the quantum system 102 at a predefined cryogenic temperature, e.g., in a range from about 1 mK to 77 K, or more particularly in a range from about 1.5 K to 4 K. The quantum system 102 may also be kept at constant air pressure, e.g., a stable vacuum.

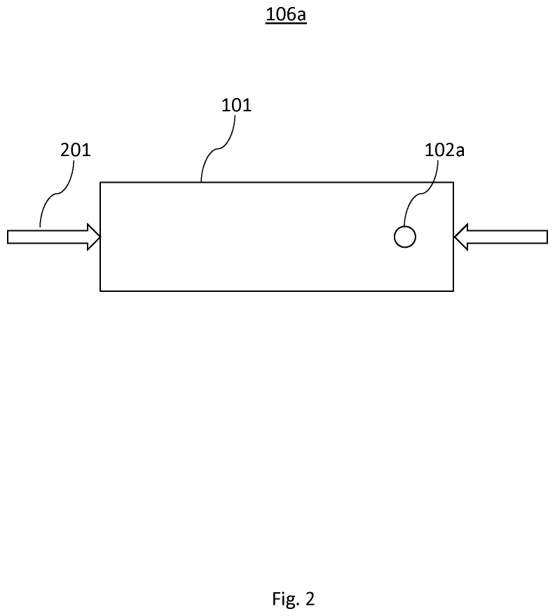

FIG. 2 shows an actuator system 106a for applying a bias mechanical stress to at least one defect 102a to 102n in a host substrate 101 of a quantum system 102, in particular the quantum system 102 of the system 100 of FIG. 1. The actuator system 106a comprises clamps for generating a clamping force, i.e., a bias mechanical stress 201 which is globally applied to the host substrate 101. The actuator system 106a may comprise micromechanical actuators as clamps for applying the clamping force.

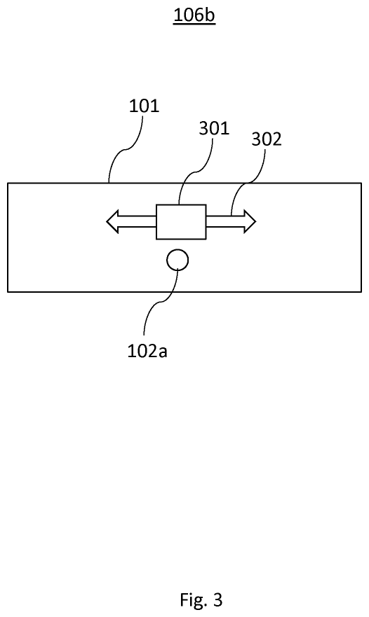

FIG. 3 shows another actuator system 106b for applying a bias mechanical stress. A component or layer 301 of a material which differs from the material of the host substrate 101 is arranged on the host material 101 or at least partially within the host material 101. Local bias mechanical stress 302 is created by lattice mismatch or thermal expansion of the component or layer 301.

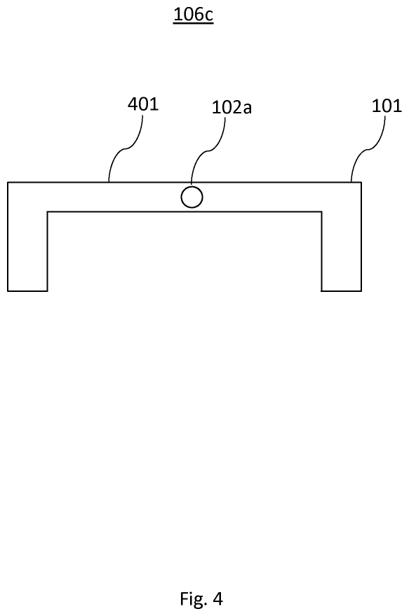

FIG. 4 shows another actuator system 106c for applying a bias mechanical stress. A cantilever or membrane 401 is provided and the host material 101 is completely or at least partially arranged on or within the cantilever or membrane 401. The cantilever or membrane 401 can be manufactured as a nano mechanical device or micro mechanical device. In other embodiments, the cantilever or membrane 401 can be structured or patterned to apply locally different strain. The cantilever or membrane 401 can be deflected to adjust the bias mechanical stress, e.g., using a piezoelectric actuator.

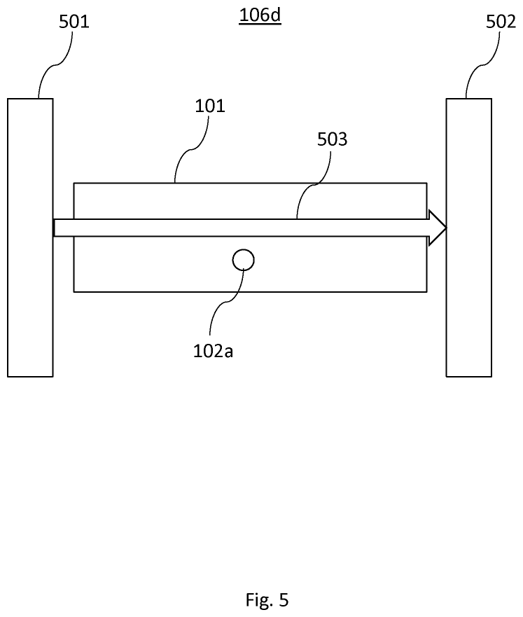

FIG. 5 shows an actuator system 106d for applying a bias electric field 503 to at least one defect 102a to 102n in a host substrate 101 of a quantum system 102, in particular the quantum system 102 of the system 100 of FIG. 1. Conducting plate capacitors 501, 502 are provided which generate a global bias electric field 503 which is applied to the host substrate 101. The plate capacitors 501, 502 may be arranged in parallel or orthogonal to the surface of the host substrate 101. In other embodiments, several pairs of plate capacitors can be provided, having different orientations. In this way, not only the strength but also the orientation of the bias electric field 503 can be adjusted.

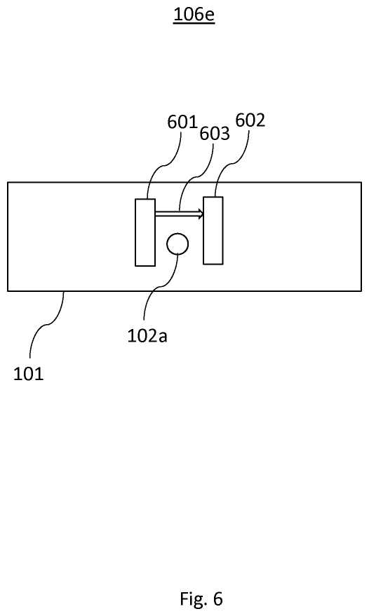

FIG. 6 shows another actuator system 106e for applying a bias electric field 603. Here, the plate capacitors 601, 602 are arranged within the host substrate 101. The plate capacitors 601, 602 can be patterned to generate locally varying bias electric fields 603.

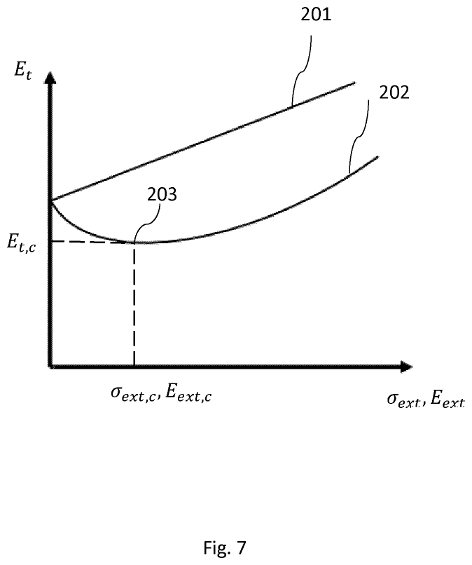

FIG. 7 schematically shows the dependence of a transition energy Eₜ of a transition between different energy levels of a defect 102a to 102n on an external mechanical stress σₑₓₜ and/or on an external electric field Eₑₓₜ. In general, the transition energy Eₜ can depend on both the external mechanical stress σₑₓₜ and on the external electric field Eₑₓₜ. For simplicity, only one dimension is shown.

Illustrated are a first transition (or transition energy branch) 201 and a second transition (or transition energy branch) 202. The external mechanical stress σₑₓₜ and/or the external electric field Eₑₓₜ modify the quantum wave function of the quantum system 102.

The transition energy of the first transition 201 depends essentially linear on the external mechanical stress σₑₓₜ and/or on the external electric field Eₑₓₜ, i.e., the transition energy is always sensitive to mechanical stress and/or electric field and there is no critical point.

For the second transition 202, there is an optimal point of the transition energy, namely the critical point (saddle point) 203 where the transition energy (frequency) of the at least one defect 102a to 102n of the quantum system 102 becomes insensitive to the external fluctuations in the environmental noise electric field or environmental noise mechanical stress. The transition energy E_{t,c} at the critical point 203 stays essentially the same under small fluctuations of the external mechanical stress σₑₓₜ and/or the external electric field Eₑₓₜ because of the zero first-order dependence on these external parameters at the critical point. Fixed values for the external mechanical stress σ_{ext,c} and the external electric field E_{ext,c} are associated with the critical point 203.

Depending on the quantum system 102, higher order insensitivity may be obtained, e.g., by varying both the bias mechanical stress and the bias electric field.

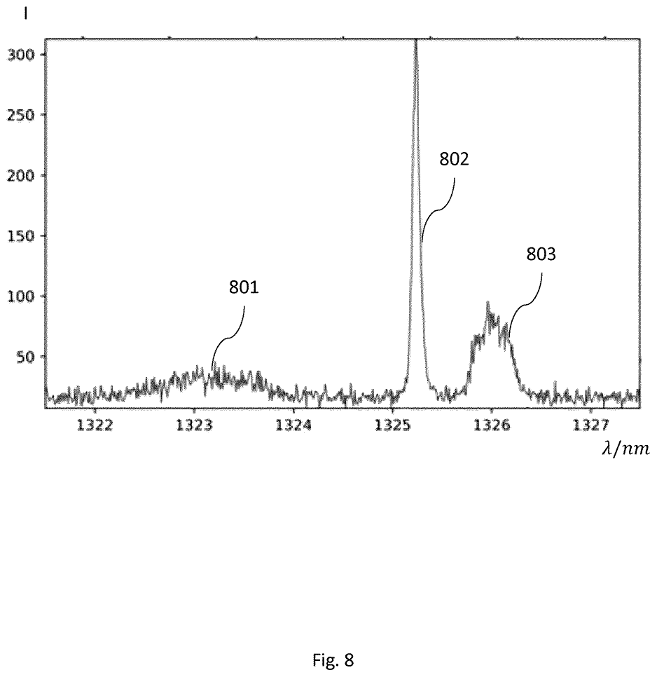

FIG. 8 shows an exemplary PLE spectrum obtained by sweeping the wavelength λ of a narrow line tunable laser and measuring the emitted photoluminescence of an ensemble of T centres in silicon. Illustrated is the intensity, I, as a function of the wavelength λ. There are three peaks 801, 802, 803 in the spectrum, corresponding to different transition energies.

The broad peak 801 at 1323 nm corresponds to a sensitive transition branch as schematically illustrated in FIG. 7 (i.e., energy 201). The two narrow peaks 802, 803 correspond to the first-order insensitive branch schematically illustrated in FIG. 7 (i.e., energy 202) and are associated with different orientations of the T centres, shifted by strain. The narrow peak 802 above 1325 nm, having an inhomogeneous linewidth of 12 GHz, is less sensitive to the environment than the peak 803 at 1326 nm, having an inhomogeneous linewidth of 25 GHZ. In some embodiments, the orientation of the T centres can be taken into account when determining a direction to apply a bias electric field and/or a bias mechanical stress.

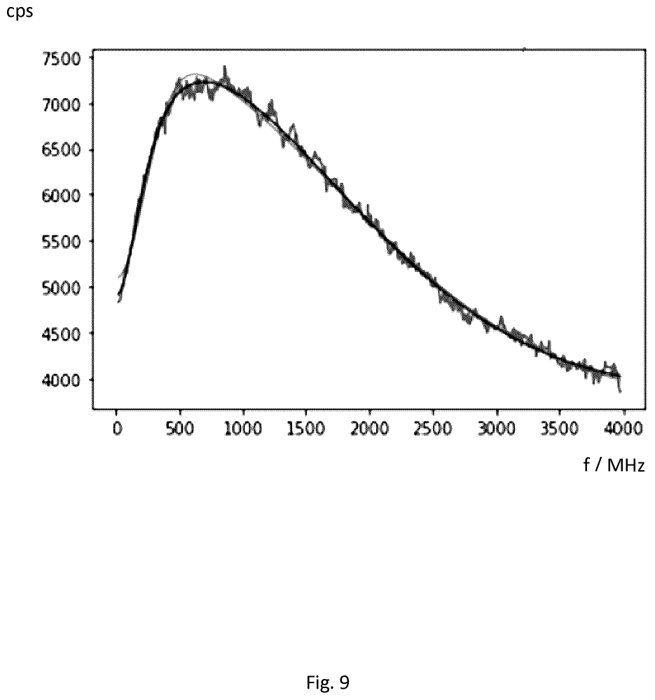

FIG. 9 shows an exemplary spectral hole burning measurement result corresponding to a first energy transition (second peak 802 above 1325 nm) in the PLE spectrum of FIG. 8. Illustrated are the counts per second cps, depending on the frequency f. In spectral hole-burning, a narrow band laser irradiates laser light of a given width and frequency. Atoms or molecules that absorb resonantly with the laser undergo a phototransformation and absorb at different frequencies, thereby creating a hole in the absorption spectrum. The hole is probed with a tunable laser and a width in the spectrum allows determining the homogeneous spectral linewidth (and therefore the value of the effective dephasing time T₂). The homogeneous spectral linewidth is around 0.5 GHz in this case.

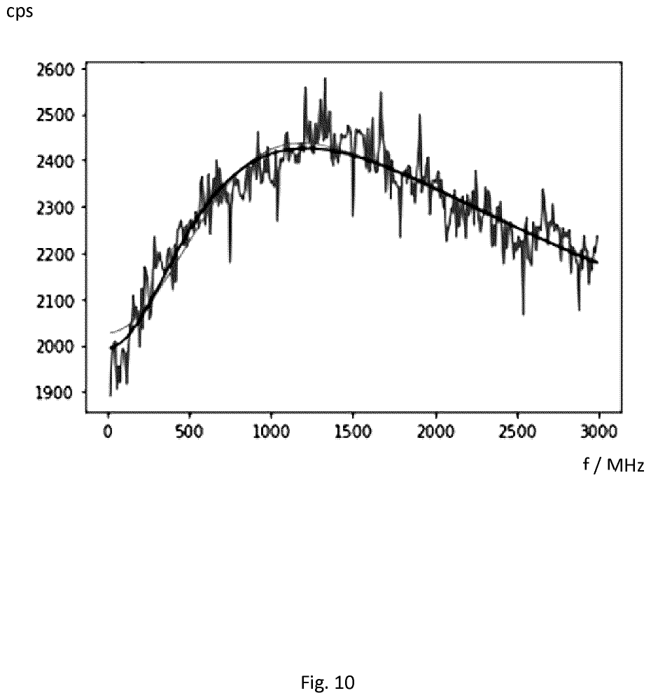

FIG. 10 shows an exemplary spectral hole burning measurement result corresponding to a second energy transition (third peak 803 at 1326 nm) in the PLE spectrum of FIG. 8. The homogeneous spectral linewidth is around 1 GHz. The reduction by at least a factor of 2 of the inhomogeneous and homogeneous linewidths between the two sets of T centres 802 and 803 indicates that quantum systems 102 can be tuned to become less sensitive to environmental fluctuations, using a bias mechanical stress and/or a bias electric field.

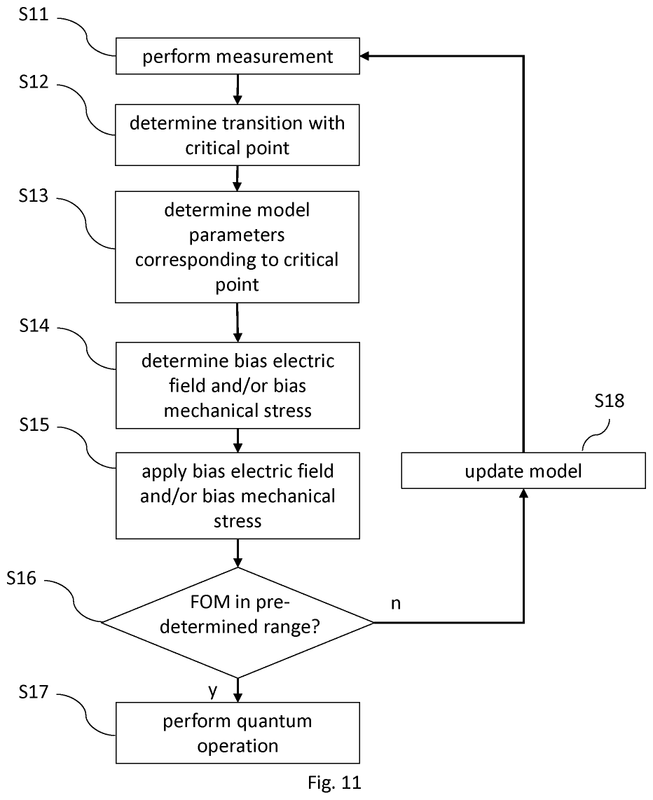

FIG. 11 shows a flow diagram illustrating a method for influencing an operating state of a quantum system, for example, the quantum system 102 of the system 100 of FIG. 1.

In a step S11, one or more measurements are performed on the quantum system 102 to characterize the quantum system 102. Based on the measurements, energy levels, symmetries of defects 102a to 102n, orientations of the defects 102a to 102n, types of interactions, quantum numbers of the energy levels, an orientation of an environmental noise electric field relative to the defects 102a to 102n, an orientation of an environmental noise mechanical stress relative to the defects 102a to 102n, a strength of an environmental noise electric field, and a strength of an environmental noise mechanical stress or a subset thereof can be determined. Other parameters that can be determined from the measurement on the quantum system 102 can include a signal intensity, a spectrum, a transition frequency, a linewidth and a coherence time. For example, a photoluminescence measurement may be performed to determine at least one figure of merit of the quantum system 102 (FOM; e.g., at least one of an inhomogeneous linewidth, a homogeneous linewidth, a coherence time, and a refocused coherence time).

A specific model of the quantum system 102 is generated based on the measurements, in particular based on the energy levels and quantum numbers of the energy levels. The model may generally comprise several parameters which are fixed based on the measurement results. There may also be several different models and the model may be selected based on the measurement results. The model comprises an external electric field and/or an external mechanical stress as free parameters.

In step S12, energy transitions having one or more critical points are determined. In an example, the model describing the quantum system 102 comprises a Hamiltonian. An exemplary Hamiltonian is disclosed in Safonov et al., “Carbon-Hydrogen Deep Level Luminescence Centre in Silicon Responsible for the T-Line,” Materials Science Forum, vol. 196-201, pp. 909-914 (1995), which is herein incorporated by reference in its entirety. The entire Hamiltonian H comprises two terms H(Σ) and H(B):

$$H = H ( ϵ ) + H ( B ) ,$$

$$H ( ϵ ) = - b {\sum }_{i} ( {J}_{i}^{2} - I ) {ϵ}_{ii} - \frac{d}{\sqrt{3}} {\sum }_{i \neq j} [ {J}_{i} {J}_{j} ] {ϵ}_{ij} ,$$

$$H ( B ) = {μ}_{B} ( {g}_{1} {\sum }_{i} {B}_{i} {J}_{i} + {g}_{2} {\sum }_{i} {B}_{i} {J}_{i}^{3} ) ,$$

where ϵᵢⱼ is the strain tensor, b and d are deformation parameters, and Jᵢ are angular momentum projection operators with

$$[ {J}_{i} {J}_{j} ] = \frac{1}{2} ( {J}_{i} {J}_{j} + {J}_{j} {J}_{i} ) .$$

Moreover, B denotes the magnetic field, where μ_{b} is the Bohr magneton, and g₁ and g₂ are hole g factors.

The Hamiltonian can also be written in terms of the stress tensor instead of the strain tensor.

From the Hamiltonian, the transition energy of transitions between different energy levels of a defect 102a to 102n of the quantum system 102 can be computed. Depending on the system, there can be one or more transitions (i.e., transition energy branches). Each transition is a function of the external electric field and/or external mechanical stress. The function can be studied to determine the presence and location of critical points in the transition energy.

Depending on the quantum system 102, there can be one or more transitions with a critical point. In such cases, one of the transition is selected based on a further criteria. The criteria may comprise selecting the transition having a critical point with the smallest higher-order gradient(s) of the transition energy with respect to the external electric field and/or external mechanical stress. Other criteria may comprise an intended use of the quantum system 102, e.g., requiring a minimal transition probability. The selection may further take into account whether the critical point is reachable, i.e., whether the critical point can be reached based on the available bias electric field and/or bias mechanical stress.

In step S13, the model parameters corresponding to the critical points are determined. That is, the external electric field and/or external mechanical stress corresponding to the critical point are computed from the model. In some embodiments, step S13 may be incorporated in step S12 or step S14.

In step S14, the bias electric field and/or bias mechanical stress for reaching the critical point are determined from the model. In an embodiment, values for an environmental noise electric field and for an environmental noise mechanical stress are determined, based on the measurement from step S11. The external electric field comprises the bias electric field and an environmental noise electric field. The external mechanical stress comprises the bias mechanical stress and an environmental noise mechanical stress. Because the external electric field and/or external mechanical stress corresponding to the critical point have been computed from the model, the corresponding bias electric field and/or bias mechanical stress can be deduced.

In step S15, the bias electric field and/or bias mechanical stress is applied to the quantum system 102, e.g., using at least one of the actuators illustrated in FIGS. 2 to 6 and being described above. The bias electric field and/or the bias mechanical stress can be applied locally or globally. A combination of local control and global control may be provided to ensure finer control of each quantum system 102. In some embodiments, only one of a bias electric field and a bias mechanical stress is applied to the quantum system 102.

In some embodiments, the bias electric field and/or the bias mechanical stress is applied in incremental steps. The bias electric field and/or the bias mechanical stress can also be applied in a single shot. A combination of biases may be applied, for example, a bias electric field may be applied during a coarse iteration, followed by a bias mechanical stress for finer tuning or vice versa. In situations where there is a plurality of quantum systems 102, a global control may be provided for applying bias electric field and/or bias mechanical stress on the plurality of the quantum systems 102.

In step S16, at least one FOM of the quantum system 102 is determined from a measurement result of another measurement on the quantum system 102 with the bias electric field and/or bias mechanical stress being applied. The FOM relates to a robustness of the quantum system 102 against environmental noise and may comprise a quantity characteristic of inhomogeneous broadening (e.g., an inhomogeneous linewidth), a quantity characteristic of homogeneous broadening (e.g., a homogeneous linewidth), a coherence time, and/or a refocused coherence time. It is determined whether the at least one FOM is within the predetermined range, e.g., smaller than a respective first threshold and/or larger than a respective second threshold.

In step S17, if the FOM is within the predetermined range, the dependence of the quantum system 102 on environmental noise is sufficiently small, i.e., the quantum system 102 is at or at least close to the critical point. A quantum operation is performed. The quantum operation may comprise an excitation to the excited state, followed by emission of a photon, which can then be used for entanglement or any other purpose. In other embodiments, the quantum system 102 does not have to be used in performing a quantum operation right away. Information about the quantum system 102 (e.g., fidelity) may be stored in a quantum register to facilitate future use.

In step S18, if the FOM is not within the predetermined range, the model is updated. For example, new measurements can be made to adjust values describing the model. The method can be repeated until the FOM is within the predetermined range.

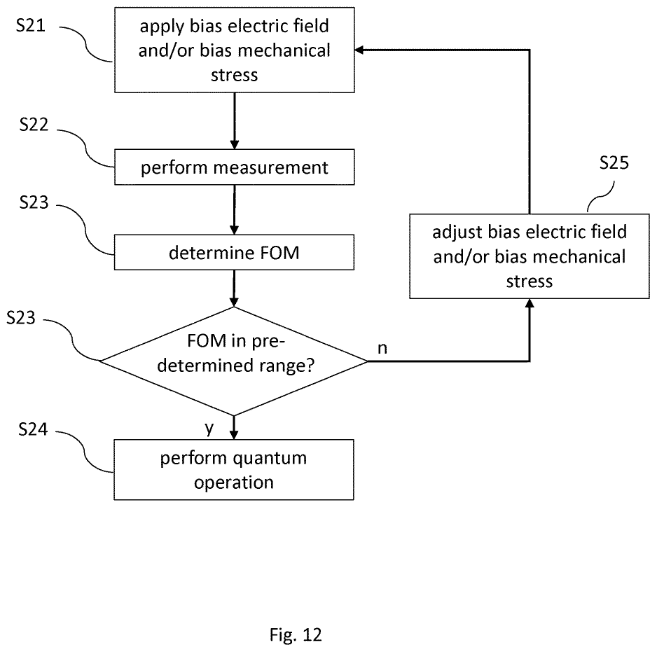

FIG. 12 shows a flow diagram illustrating a method for influencing an operating state of a quantum system, for example, the quantum system 102 of the system 100 of FIG. 1. The quantum system 102 comprises at least one defect, defect complex or impurity 102a to 102n in a host material (host substrate 101) as described above. The at least one defect, defect complex or impurity 102a to 102n comprises a transition between different energy levels.

In step S21, a bias electric field and/or bias mechanical stress is applied to the quantum system 102, e.g., using at least one of the actuators illustrated in FIGS. 2 to 6 and being described above.

In step S22, a measurement is performed on the quantum system 102, e.g., a photoluminescence measurement.

In step S23, a FOM is determined, based on the result of the measurement. The FOM contains information on the robustness of the quantum system 102 against environmental noise. The FOM may comprise a quantity characteristic of inhomogeneous broadening, a quantity characteristic of homogeneous broadening, a coherence time, and/or a refocused coherence time. The step further includes determining whether the at least one FOM is within a predetermined range, e.g., smaller than a respective first threshold and/or larger than a respective second threshold value.

The predetermined range represents the range where the environmental noise effects remain tolerable.

In step S24, if the FOM is within the predetermined range, the effect of the environmental noise on the quantum system 102 is sufficiently negligible. The quantum system may then be used in performing a desired quantum operation or for any other quantum applications. As will be appreciated by those of skill in the art, the systems, methods, and devices described in this disclosure facilitates operating a quantum system in the vicinity of environmental noise while preserving the integrity of the quantum system.

In step S25, if the FOM is outside the predetermined range, the bias electric field and/or bias mechanical stress is adjusted and steps S21 to S23 are repeated. The method can be repeated until the FOM is in the predetermined range.

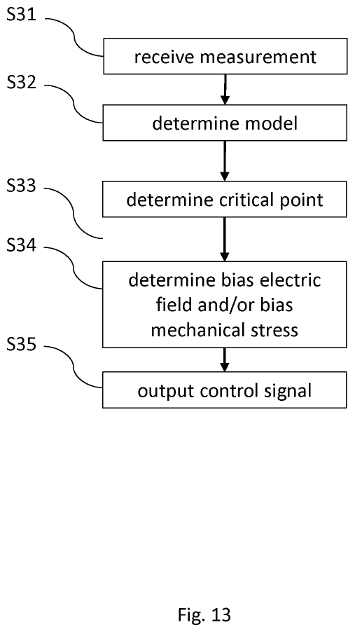

FIG. 13 shows a flow diagram illustrating a computer-implemented method for controlling an actuator, for example, the actuators shown in FIGS. 2 to 6 and as described previously.

In step S31, a result from a measurement performed on a quantum system 102 is received by a computing device, e.g., the processor 105b illustrated in FIG. 1 and described above. The quantum system 102 comprises at least one defect, defect complex or impurity 102a to 102n in a host material. The at least one defect, defect complex or impurity 102a to 102n comprises a transition between different energy levels.

In step S32, the computing device determines a model describing the quantum system 102, based on the result of the measurement. The computing device may have access to a plurality of models, stored in a memory 105c. Each model can have several parameters. The specific model and some of the parameters are fixed based on the measurements. For example, the quantum system 102 may comprise T centres and a Hamiltonian corresponding to such quantum systems is selected. The model still comprises free parameters, e.g., the external electric field and the external mechanical stress.

In step S33, the computing device determines at least one critical point of a transition energy of the transition as a function of an external electric field and/or an external mechanical stress, using the determined model, e.g., by solving for a critical point of the transition energy from a Hamiltonian function.

In step S34, the computing device determines the strength and/or direction of a bias electric field and/or a bias mechanical stress, necessary to bring the at least one defect, defect complex or impurity 102a to 102n to or close to the determined critical point, using the determined model.

In step S35, at least one control signal is outputted to an actuator to control the actuator to apply the determined bias electric field and/or the determined bias mechanical stress to the quantum system 102. The actuator may comprise at least one of the actuators illustrated in FIGS. 2 to 6 and being described above.

The devices, apparatuses and systems described in the present disclosure may comprise electronic components and circuits known to those skilled in the art. Therefore, details of the circuitry and its components have not be explained in any greater extent than that considered necessary for the understanding and appreciation of the underlying concepts of the present disclosure.

Where reference is made to a component, such as a device, component, software module or the like, the reference to that component is intended to include as equivalents any component being functionally equivalent, i.e., performing the same function, even though the component is not necessarily structurally equivalent to the component that performs in the exemplary embodiments.

In the above description, embodiments have been described with reference to specific details, e.g., parts of a method, components, materials, and the like. A person skilled in the art will understand that embodiments may be implemented without one or more of these specific details.

All of the US patents, US patent application publications, US patent applications, foreign patents, foreign patent applications, and non-patent publications referred to in this specification, or referred to on any application data sheet, are incorporated by reference in their entireties for all purposes herein.

A person skilled in the art may understand that certain method steps may be described or depicted in a particular order of occurrence while such specificity with respect to sequence is not actually required.

Phrases like “an embodiment” and “another embodiment” are used in the sense that particular features described in connection with the embodiment are included in at least one embodiment. Those phrases do not necessarily all refer to the same embodiment. Terms such as “first”, “second”, “third”, and so on, are used to distinguish between the elements described by these terms. These terms do not necessarily imply any temporal or other prioritization of such elements.

As used herein, the singular forms “a,” “one,” and “the” are also intended to encompass the plural forms unless the context indicates otherwise. In addition, it is understood that the expressions “includes” and/or “including” when used in this specification relates to the presence of features, numbers, steps, operations, elements, and/or components, but does not exclude the presence or addition of one or more features, numbers, steps, operations, elements and/or combinations thereof. As used herein, the term “and/or” includes any and all combinations of one or more of the associated listed elements.

Terms such as “horizontal”, “vertical”, “upper”, “lower”, “above”, “below”, “forward” and “backward” refer to particular orientations of components and/or events in time and/or space. The skilled person understands that may therefore depend on the specific orientation and may change if the components and/or events are oriented differently.

In this specification, the present disclosure has been described with reference to the accompanying drawings, in which exemplary embodiments are shown. However, the present disclosure is not limited to the described exemplary embodiments described and may be modified in various different ways. Consequently, the drawings and description are intended to be illustrative in nature and not limiting. Identical reference numbers denote identical elements in the specification.

As used herein, the terms “about,” “approximately,” or “substantially” refer to a value, amount, or property that is close to the specified value, amount, or property. The value, amount, or property is such that a desired function or result is still achieved. According to an example, an amount may be less than 10%, 5%, 1%, or 0.1% of the specified amount, respectively.

Even if the disclosure has been described and illustrated with reference to illustrative embodiments, various modifications may be made without departing from the scope of the present disclosure as defined in the claims. Such modifications may comprise replacement of features, components and/or method steps with equivalent features, components and/or method steps; mixing of features, components and/or method steps from different embodiments; and/or omitting or combining features, components and/or method steps from described embodiments. All such modifications and variations are intended to be included herein within the scope of this disclosure and protected by the following claims.

1. A method for influencing an operating state of a quantum system, wherein the quantum system comprises at least one defect, defect complex or impurity in a host material, wherein the method comprises:
determining a transition between different energy levels of the at least one defect, defect complex or impurity, wherein a transition energy of the transition as a function of an external electric field and/or external mechanical stress has an associated critical point;
determining a bias electric field and/or a bias mechanical stress for bringing the at least one defect, defect complex or impurity to or close to the critical point of the transition energy, wherein the external electric field comprises the bias electric field and an environmental noise electric field, and wherein the external mechanical stress comprises the bias mechanical stress and an environmental noise mechanical stress; and
causing the determined bias electric field and/or the determined bias mechanical stress to be applied to the quantum system.

2. The method according to claim 1, further comprising:
determining the critical point of the transition energy, using a model describing the quantum system.

3. The method according to claim 2, wherein the model comprises a Hamiltonian function of the quantum system, and determining the critical point of the transition energy comprises determining a critical point of the Hamiltonian function.

4. The method according to claim 2, further comprising:
selecting the critical point of the transition energy from a plurality of critical points of the transition energy which are determined using the model.

5. The method according to claim 4, wherein the critical point is selected based on having a first-order gradient of the transition energy that is smaller than a predetermined number and having the least second-order gradient of the transition energy or higher-order gradient of the transition energy amongst the plurality of critical points.

6. The method according to claim 4, wherein a critical point of the plurality of critical points is selected which is reachable by causing the bias electric field to be applied and/or by causing the bias mechanical stress to be applied within a predefined and practically controllable range.

7. The method according to claim 4, wherein a critical point of the plurality of critical points is selected based on a predefined quantum operation to be performed on the quantum system.

8. The method according to claim 2, further comprising:
obtaining, from a measurement on the quantum system, a measurement result characteristic of the quantum system;
wherein the model describing the quantum system is selected based on the measurement result from the measurement.

9. The method according to claim 8, wherein the measurement comprises:
a measurement of the energy levels of the quantum system and of at least one quantum number of the energy levels;
a measurement of types of interactions of the quantum system;
a measurement of piezoelectric properties of the host material of the quantum system;
a measurement of a coherence time of the quantum system;
a measurement of a symmetry of the at least one defect, defect complex or impurity;
a measurement of a signal intensity of an optical signal emitted by the at least one defect, defect complex or impurity;
a measurement of a homogeneous linewidth of a spectrum of the at least one defect, defect complex or impurity;
a measurement of an inhomogeneous linewidth of the spectrum of the at least one defect, defect complex or impurity;
a measurement of the transition energy of the transition;
a measurement of a size and/or orientation of the environmental noise electric field and/or the environmental noise mechanical stress; or
a size and/or orientation of the bias electric field and/or the bias mechanical stress.

10-20. (canceled)

21. The method according to claim 1, further comprising:
obtaining a result of a measurement performed on the quantum system; and
determining the bias electric field and/or the bias mechanical stress, based on the result of the measurement.

22. The method according to claim 21, wherein the measurement comprises a photoluminescence measurement of the quantum system,
wherein the photoluminescence measurement comprises:
a measurement of a homogeneous linewidth of a spectrum of the at least one defect:
a measurement of an inhomogeneous linewidth of the spectrum of the at least one defect; or
a measurement of a spectral density of the environmental noise.

23-26. (canceled)

27. The method according to claim 1, wherein the at least one defect comprises a luminescent defect, and wherein the transition comprises an optical transition.

28. The method according to claim 27, wherein the at least one defect comprises a spin defect.

29. (canceled)

30. The method according to claim 27, wherein the transition comprises a zero phonon line, ZPL, transition.

31-32. (canceled)

33. The method according to claim 1, wherein:
one of the applied bias mechanical stress and the applied bias electric field is homogeneous over the quantum system, and wherein the other of the applied bias mechanical stress and the applied bias electric field varies locally over the quantum system; or
both the applied bias mechanical stress and the applied bias electric field are locally varied over the quantum system.

34-44. (canceled)

45. The method according to claim 1, further comprising:
causing a quantum operation to be performed with the quantum system,
wherein the applied bias electric field and/or bias mechanical stress is adjustable when performing the quantum operation.

46-47. (canceled)

48. The method according to claim 1, wherein the quantum system has a non-vanishing electric dipole moment.

49-59. (canceled)

60. A device for influencing an operating state of a quantum system, wherein the quantum system comprises at least one defect, defect complex or impurity in a host material, wherein the device comprises:
a computing device configured to:
determine a transition between different energy levels of the at least one defect, defect complex or impurity, wherein a transition energy of the transition as a function of an external electric field and/or external mechanical stress has a critical point; and
determine a bias electric field and/or a bias mechanical stress for bringing the at least one defect, defect complex or impurity to or close to the critical point of the transition energy of the determined transition as a function of the external electric field and/or the external mechanical stress, wherein the external electric field comprises the bias electric field and an environmental noise electric field, and wherein the external mechanical stress comprises the bias mechanical stress and an environmental noise mechanical stress; and
an actuator configured to apply the determined bias electric field and/or the determined bias mechanical stress to the quantum system.

61. A system, comprising:
a host substrate;
a quantum system comprising at least one defect, defect complex or impurity in the host substrate; and
a device for influencing an operating state of the quantum system according to claim 60.

62-66. (canceled)

67. A non-transitory, computer-readable storage medium comprising executable program code configured to, when executed by a computing device;
determine a transition between different energy levels of at least one defect, defect complex or impurity in a host material, wherein a transition energy of the transition as a function of an external electric field and/or external mechanical stress has an associated critical point;
determine a bias electric field and/or a bias mechanical stress for bringing the at least one defect, defect complex or impurity to or close to the critical point of the transition energy, wherein the external electric field comprises the bias electric field and an environmental noise electric field, and wherein the external mechanical stress comprises the bias mechanical stress and an environmental noise mechanical stress; and
cause the determined bias electric field and/or the determined bias mechanical stress to be applied to the quantum system.
